(19) United States
(12) Patent Application Publication
(10) Pub. No.: US 2024/0030075 A1
(43) Pub. Date: Jan. 25, 2024

(54) DIE SEALANT FOR CHIP PACKAGING AND PACKAGING STRUCTURE

(71) Applicant: Wuhan Choice Technology Co,Ltd, Wuhan (CN)

(72) Inventors: De WU, Wuhan (CN); Zongxiao HU, Wuhan (CN); Shuhang LIAO, Wuhan (CN); Junxing SU, Wuhan (CN)

(73) Assignee: Wuhan Choice Technology Co,Ltd, Wuhan (CN)

(21) Appl. No.: 18/307,770

(22) Filed: Apr. 26, 2023

Related U.S. Application Data
(63) Continuation of application No. PCT/CN2022/099205, filed on Jun. 16, 2022.

(30) Foreign Application Priority Data
Oct. 9, 2021 (CN) 202111177372.8

(51) Int. Cl. H01L 23/06; C09K 3/10; H01L 23/00

(52) U.S. Cl. CPC H01L 23/06; C09K 3/1006; H01L 24/29; H01L 23/562; C09K 2003/1087; H01L 2224/29386; H01L 2924/1659

(57) ABSTRACT

The present application discloses a die sealant for chip packaging and a packaging structure, wherein epoxy resin adopted in the die sealant has flexible units such as polyether. In combination with the compounding of components such as a curing agent and a diluent, good flexibility and strength are achieved, and warpage is effectively reduced, wherein the warpage can be reduced to 0 mm, the modulus can reach up to 8 GPa or above, good silicon adhesion is achieved, and a silicon wafer can be effectively protected from bending cracks caused by warpage. Moreover, by adding a p-tert-butylphenol epoxy resin diluent, impacts of a monofunctional aliphatic diluent on a curing system can be further reduced effectively, and the flexibility and modulus of the die sealant can be further improved.

### CROSS-REFERENCE TO RELATED APPLICATIONS

The application claims priority to Chinese patent application No. CN202111177372.8, filed on Oct. 9, 2021, the entire contents of which are incorporated herein by reference.

### TECHNICAL FIELD

The present application relates to the technical field of semiconductor packaging, in particular to a die sealant for chip packaging and a packaging structure.

### BACKGROUND

With the development of a semiconductor technology, in the field of component packaging of electronic part devices, resin scaling has gradually become a mainstream due to its production convenience and cost advantages. In recent years, electronic parts on a printed circuit board have been gradually mounted at high density. Subsequently, in semiconductor devices, surface-mounted packaging is rapidly developing as comparison with original pin-inserted packaging. A surface-mounted IC (Integrated Circuit Chip) can increase the mounting density and reduce the mounting height, thereby achieving thin and small packaging and reducing the packaging wall thickness.

In addition to a commonly used transfer dieing method, a die pressing method can also be adopted to package an electronic component by using resin, that is, the electronic component, such as a silicon wafer on which chips have been etched, is put in a die, and then, a resin packaging material is given and die-pressed, so that resin sealing is performed. However, in this process, due to die pressing operation and temperature change, a die sealing material is easy to warp to result in cracks and fissures caused by excessive bending of the silicon wafer, thereby affecting the operation on subsequent work sections and also easily resulting in a defect rate of the chips.

### SUMMARY

The present application provides a die sealant for chip packaging, which has high modulus, low warpage and good flexibility and can effectively reduce silicon wafer cracks and fissures caused by excessive bending of a silicon wafer.

The present application provides the following technical solutions.

On one hand, the present application provides a die sealant for chip packaging, including the following components in parts by weight: 5-20 parts by weight of epoxy resin, 5-20 parts by weight of curing agent, 0.1-1.2 parts by weight of curing accelerator, 70-100 parts by weight of inorganic filler, 0.5-2.5 parts by weight of coupling agent and 0.1-15 parts by weight of diluent;

wherein the epoxy resin has a structure as shown in a formula (I):

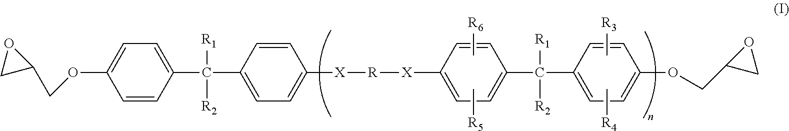

in the formula (I), each of R1 and R2 is independently selected from linear or branched alkyls of H or C1-C10 each of R3, R4, R5 and R6 is independently selected from a hydrogen atom, a methyl or a halogen, X is selected from —O—, —COO— or —OCH(CH3)O—, R is selected from any one of an alkylene and a polyether skeleton, and n is an integer within a range of 1-10.

In some embodiments, in the formula (I), R is —CH2CH2—(OCH2CH2)m-n- or —CH(CH3)CH2—(OCH(CH3)CH2)m—, wherein in is an integer within a range of 0-5.

In some embodiments, the epoxy resin has a structure as shown in a formula (II):

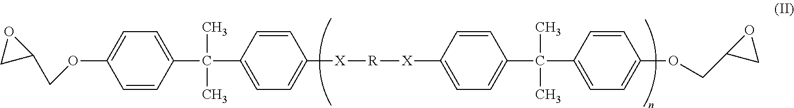

wherein X is —OCH(CH3)O— and n is an integer within a range of 1-5.

In some embodiments, the inorganic filler is silica, wherein a particle size of silica is within a range of 0.1-75 μm.

In some embodiments, the curing agent is selected from at least one of tetrahydrophthalic anhydride, hexahydrophthalic anhydride, methylhexahydrophthalic anhydride, phthalic anhydride, tetrahydrophthalic anhydride, methyl nadic anhydride and phenol-arylalkyl phenolic resin.

In some embodiments, the curing agent includes methyl nadic anhydride and methylhexahydroplithalic anhydride which are in a mass ratio of (1-2):1.

In some embodiments, the diluent is a p-tert-butylphenol epoxy resin diluent having the total chloride content of less than or equal to 200 ppm.

In some embodiments, the die sealant for chip packaging further contains 0.02-0.1 part by weight of colorant.

In some embodiments, the die sealant consists of the following components in parts by weight: 5-20 parts by weight of the epoxy resin, 5-20 parts by weight of the curing agent, 0.1-1.2 parts by weight of the curing accelerator, 70-100 parts by weight of the inorganic filler, 0.1-15 parts by weight of the diluent and 0.02-0.1 part by weight of the colorant.

On the other hand, the present application further provides a chip packaging structure. The chip packaging structure includes chips etched on a silicon wafer and a packaging layer covering the silicon wafer, wherein the packaging layer is in contact with the silicon wafer and covers the chips, and the packaging layer includes the die sealant of any one of claims 1-9.

Beneficial Effects:

the die sealant provided by the present application adopts the epoxy resin having flexible units such as polyether. In combination with the compounding of the components such as the curing agent and the diluent, good flexibility and strength are achieved, and warpage is effectively reduced, wherein the warpage can be reduced to 0 mm, the modulus can reach up to 8 GPa or above, good silicon adhesion is achieved, and a silicon wafer can be effectively protected from bending cracks caused by warpage. Moreover, it is also found by an applicant of the present application that, by adding the p-tert-butylphenol epoxy resin diluent, impacts of a monofunctional aliphatic diluent on a curing system can be further reduced effectively, and the flexibility and modulus of the die sealant can be further improved.

### BRIEF DESCRIPTION OF DRAWINGS

In order to describe the technical solutions in the embodiments of the present application more clearly, the accompanying drawings required for describing the embodiments will be briefly introduced below. Apparently, the accompanying drawings in the following description show only some embodiments of the present application, and those skilled in the art may still derive other accompanying drawings from these accompanying drawings without creative efforts,

FIG. 1 is a schematic diagram of a top-view structure of a to-be-packaged silicon wafer on which a chip is etched in embodiments of the present application; and

FIG. 2 is a chip packaging structure provided in embodiments of the present application.

### DETAILED DESCRIPTION OF THE EMBODIMENTS

The technical solutions in the embodiments of the present application will be clearly and completely described below. Apparently, the described embodiments are only a part of the embodiments of the present application, but not all of the embodiments. Based on the embodiments of the present application, all other embodiments obtained by those skilled in the art without creative effort shall fall within the protection scope of the present application. In addition, it should be understood that the implementations described herein are only intended to describe and explain the present application, rather than to limit the present application. In the description of the present application, the term “including” refers to “including, but not limited to”. Various embodiments of the present application can exist in a form of a range. It should be understood that the description in a form of a range is only for the purposes of convenience and simplicity and should not be understood as an inflexible limitation on the scope of the present application. Therefore, it should be considered that all possible sub-ranges and a single value in the range have been specifically disclosed in the description for the range. For example, it should be considered that sub-ranges such as 1-3, 1-4, 1-5 and 2-4 and a single number such as 1, 2, 3, 4 or 5 within a range to which the single number belongs have been specifically disclosed in the description for the range from 1 to 5, and it is applicable regardless of the range. In addition, a value range indicated herein refers to any referenced numbers (fractions or integers) within the referred range.

Embodiments of the present application provide a die sealant for chip packaging, including the following components in parts by weight: 5-20 parts by weight of epoxy resin, 5-20 parts by weight of curing agent, 0.1-1.2 parts by weight of curing accelerator, 70-100 parts by weight of inorganic filler and 0.1-15 parts by weight of diluent;

wherein the epoxy resin has a structure as shown in a formula (I):

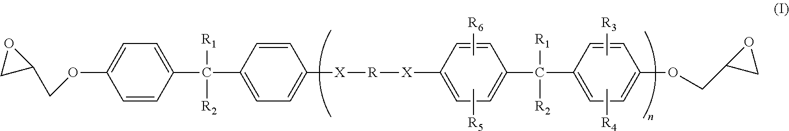

in the formula (I), each of R1 and R12 is independently selected from linear or branched alkyls of H or C1-C10, each of R3, R4, R5 and R6 is independently selected from a hydrogen atom, a menthyl or a halogen, X is selected from —O—, —COO— or —OCH(CH3)O—, R is selected from any one of an alkylene and a polyether skeleton, and n is an integer within a range of 1-10.

In the resent application, the halogen is selected from a fluorine atom or a chlorine atom, wherein the fluorine atom is preferred.

The die sealant for chip packaging provided in the embodiments of the present application adopts the epoxy resin as shown in the formula (I). By using flexible fragments and low-polarity chain segments such as the X group and the R group and combining with a curing system and the diluent, the die sealant has good flexibility ad strength and good silicon adhesion and effectively reduces warpage.

For the epoxy resin used in the embodiments of the present application, the R group in the formula (I) can be —CH2CH2—(OCH2CH2)m- or —CH(CH3)CH2—(OCH(CH3)CH2)m—, wherein m is an integer within a range of 0-5. For example, when m=0, the R group is a linear or branched alkylene. When m is equal to any one of integers ranging from 1 to 5 the R group is the polyether skeleton.

In some specific embodiments, the epoxy resin can have a structure as shown in a formula (II):

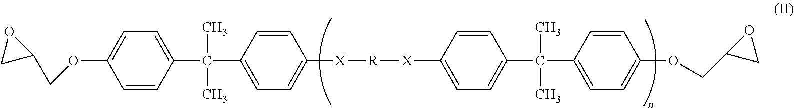

wherein X is —OCH(CH3)O—, and n is an integer within a range of 1-5.

In some embodiments, in view of a curing rate and strength in a chip packaging process, an epoxy equivalent of the epoxy resin is 400-450 g/eq. The viscosity of the epoxy resin (25° C., E-type viscometer) is 100005000 mPa·s, and the number-average molecular weight is 700-900. Such epoxy resin can achieve good flexibility and high modulus. In some specific embodiments, EXA-4850-150 from the DIC corporation can be selected to be used.

In embodiments of the present application, the inorganic filler can select and use silica having a particle size within a range of 0.1-75 μm, wherein the use amount of silica is 70-100 parts by weight. Due to the selection and use of the epoxy resin on a flexible chain segment in the epoxy resin die sealant provided by the present application, low viscosity and good flexibility are achieved, and therefore, a higher silica filling content can be achieved, which further enables a packaging layer to have a low thermal expansion coefficient. In some embodiments, silica can be fumed silica or molten silica having a particle size of 0.1-75 μm or 1-50 μm.

The curing agent is selected from at least one of tetrahydrophthalic anhydride, hexahydrophthalic anhydride, methylhexahydrophthalic anhydride, phthalic anhydride, tetrahydrophthalic anhydride, methyl nadic anhydride (methyl-5-norbornene-2,3-dicarboxylic anhydride) and phenol-arylalkyl phenolic resin. The use amount of the curing agent is 5-20 parts by weight, such as 10-12 parts. The use amount of the curing agent is not specifically limited and can be selected and determined by the skilled in the art according to a construction condition and a curing rate. In some embodiments, the curing agent is preferably a compound of methyl nadic anhydride and methylhexahydrophthalic anhydride, wherein the compounding ratio is (1-2):1, and more preferably 1:1. In some embodiments, a ratio of the use amount of the epoxy resin to the use amount of the curing agent is (1-2): 1, and preferably 1:1.

The curing accelerator can also be further added in the embodiments of the present application, there are no specific limitations on the kind of the curing accelerator, and the curing accelerator can be selected from imidazole or N,N-dimethylaniline. The curing agent and the curing accelerator are combined with the epoxy resin in the embodiments of the present application to achieve processing properties such as the curing rate and flowability required by a packaging material.

The die sealant contains 0.5-2.5 parts by weight of coupling agent. The coupling agent can improve the compatibility among all the components and can particularly help these particles to be uniformly dispersed in an epoxy resin system to improve the compatibility of the system under the condition that silica filler and a toughening agent which are in a large ratio are added. In embodiments of the present application, the coupling agent is a silane coupling agent having an epoxy group, which is, for example, selected from, but not limited to any one of γ-glycidoxy propyl trimethoxy silane, γ-glycidoxy propyl triethoxy silane, γ-glycidoxy propyl tripropoxy silane and γ-glycidoxy propyl tributoxy silane. An epoxy functional group carried by the silane coupling agent having the epoxy group can better from a cured crosslinked network together with the epoxy resin in a curing process, thereby further improving the compatibility of the system.

The die sealant contains 0.1-1.5 parts by weight of diluent so as to be capable of reducing the viscosity of a packaging material under the condition that material properties are not changed as much as possible. The diluent can be selected from an epoxy diluent, such as any one of a p-tert-butylphenol epoxy resin diluent or a monofunctional aliphatic diluent and a bifunctional aliphatic diluent, known in the art. It is worth noting, that the p-tert-butylphenol epoxy resin diluent shows more excellent effects in a die sealant system in the embodiments of the present application, the possible reason thereof is that the p-tert-butylphenol epoxy resin diluent has less impacts on the curing system and can maintain the more stable curing properties of the epoxy resin. Moreover, the diluent should contain no halogens or should be low in halogen content and is expected to have a total chloride content of less than or equal to 200 ppm. In some embodiments, the selectable diluent is ADEKA ED-509S or ERISYS GE-11. The use amount of the diluent should not exceed 1.5% so that the lower total chloride content is maintained.

In some embodiments, a chip packaging material further includes 0.02-0.1 part by weight of colorant. In some embodiments, the pigment is carbon black. The colorant gives the packaging layer a color, so that the packaging layer presents a different-color appearance, and it is convenient to print characters on chips.

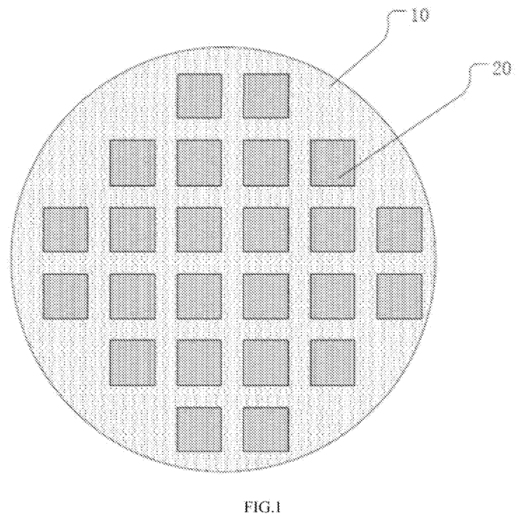

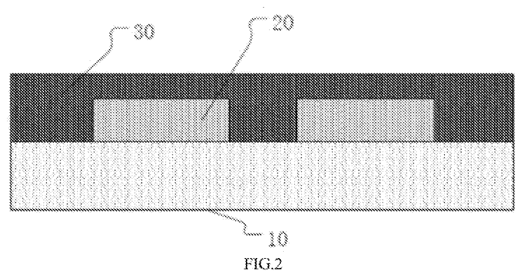

Embodiments of the present application further provide a chip packaging structure, with reference to FIG. 1 and FIG. 2, the packaging structure includes a silicon wafer 10 and chips 20 etched on the silicon wafer, wherein a packaging layer 30 is in partial contact with the silicon wafer 10, and the packaging layer 30 includes the die sealant provided in the embodiments of the present application.

It can be understood by the skilled in the art that, as shown in FIG. 1, the plurality of chips 20 can be etched on the silicon wafer 10 at a spacing. The die sealant in the embodiments of the present application can be used for wafer-level packaging or single or more chip packaging.

In some embodiments, the packaging layer 30 has a thickness of 50-200 μm.

In some embodiments, the packaging layer 30 covers backs of the chips; and in some other embodiments, the packaging layer 30 covers the peripheries of the chips 20 and are filled in gaps among the chips 20, that is, the die sealant completely covers the chips 20 so as to provide complete protection for the chips 20.

Correspondingly, embodiments of the present application further provide a chip packaging method for forming the above-mentioned packaging structure. The chip packaging method includes the following steps:
to-be-packaged chips are put in a die, wherein the chips are disposed on a silicon wafer;
the die sealant in the embodiments of the present application is provided, and the liquid die sealant is added into the die to fill gaps of the chips and cover to-be-packaged surfaces of the chips;
die pressing is performed by adopting a die press; and
curing is performed to complete chip packaging.

In some embodiments, the step that the die sealant in the embodiments of the present application is provided includes: various components of the packaging material are provided according to a ratio and are uniformly mixed to form the die sealant.

In some embodiments, the step of mixing includes: uniform stirring, mixing and vacuum defamation to prepare the die sealant.

It can be understood by the skilled in the art that the above-mentioned step of mixing can be implemented by adopting a manner known in the art, as along as a die sealant dispersion system with various components uniform in dispersion and good in compatibility can be provided.

For example, a rotational or revolutional centrifugal stirrer can be adopted for stirring and mixing, and the temperature is controlled at 70° C. or below. A three-roller or double-roller mixer can be adopted for mixing, and a gap between the rollers depends on the maximum particle size of the filler, for example, it is equal to or slightly greater than the maximum particle size of silica. In some implementations, the gap between the rollers at a feeding end is 2-3 times as large as the maximum particle size of the filler, and the gap between the rollers at a discharging end is 1.5-2 times as large as the maximum particle size of the filler, for example, in the embodiments of the present application, the gap between the rollers is 30-80 μm so that the distribution of the inorganic filler in a resin system can be sufficiently dispersed. During mixing, the temperature is controlled to be less than or equal to 50° C., the situation that a material is cured in advance due to overhigh temperature is avoided. The temperature of vacuum stirring defoamation is controlled to be less than or equal to 50° C.

Optionally, in some embodiments of the present application, the curing temperature in the curing step is 120-180° C. The curing process can further improve the hardness of the packaging material so that the chips are better protected.

Optionally, in some embodiments of the present application, the packaging material is applied to the backs of the chips and is cured to form the packaging layer, which means that the packaging material is cast on the backs and peripheries of the chips, and then, the packaging material is filled in the die by using a die pressing process and is cured to form the packaging layer.

Optionally, in some embodiments of the present application, the die pressing process includes: pre-pressing and press-fitting performed by the die press, pressure relief for takeout, and heating and curing in a drying oven. There are no specific limitations on parameters of the die pressing process, and working parameters of the die press can be determined by the skilled in the art according to the die pressing process and specific scales of the wafer and the die known in the art.

The present application will be specifically described below with specific embodiments, and the following embodiments are only parts of the embodiments of the present application, but are not intended to limit the present application.

### EMBODIMENT

Various components of a packaging material are weighted according to table 1, compounded, mixed, defoamed and tubulated to prepare an epoxy resin die sealant.

A mixing process includes: centrifugal stirring is performed at 70° C. for 30 min, and a revolution speed is 1200-1300 r/min; mixing is performed at the three-roller mixing temperature of 50° C. for 1.5 h. and a roller spacing is 40 μm; the centrifugal stirring defoamation temperature is 50° C., and stirring is performed for 10 min; and a revolution speed is 1200-1500 r/min.

A thermal expansion coefficient CTE1 of a packaging adhesive in each of embodiments and comparative examples is tested, wherein the test method includes: after the packaging adhesive is cured at 130° C. for 1 h, a sample meeting a standard ASTM E831-2019 requirement is prepared, and then, a thermal expansion coefficient of the sample is tested.

The warpage of the packaging adhesive in each of the embodiments and the comparative examples is tested, wherein the test method includes:

a Si wafer is covered with a packaging adhesive with the thickness of 200 μm, is cured at 130° C. for 1 h, is taken out after being cooked and is put on a horizontal desktop, one side of a glass slide is pressed by a heavy object and a distance from the other side to the desktop is measured by using a caliper.

The viscosity of the packaging adhesive, in each of the embodiments and the comparative examples is tested with reference to standard ASTM D2196-2018 the constant temperature of the sample is 25° C. a Brookfield viscometer is used, and a SC4-14 rotor with the rotating speed of 2-10 rpm is selected.

A modulus test method includes: the size of a prepared test sample is 55 mm*10 mm*2 mm, and the storage modulus is teste by adopting art ASTME2254-2018 standard method.

The silicon interface adhesion of the packaging adhesive in each of the embodiments and the comparative examples is tested by using a method referring to the standard ASTM D1002-2010, a liquid die sealant is respectively dispensed in a square area of 5 mm×5 mm on a silicon wafer on a test interface and is cured at 150° C. for 1 h, and then, the shear bond strength is tested by using a universal tensile machine.

TABLE 1
die Sealant Composition Table and Performance Test Results

| Component (in | Embodi- | Embodi- | Embodi- | Embodi- | Embodi- | Comparative | Comparative |
|---|---|---|---|---|---|---|---|
| parts by weight) | ment 1 | ment 2 | ment 3 | ment 4 | ment 5 | example 1 | example 2 |
| Epoxy resin | 10 | 10 | 20 | 10 | 10 | / | 25 |
| EXA-4850-150 | | | | | | | |
| Epoxy resin | / | 5 | / | / | 5 | 15 | 10 |
| NPEF-170 | | | | | | | |
| Methyl nadic | 7 | 10 | 10 | 14 | 10 | 9 | 14 |
| anhydride | | | | | | | |
| Methylhexahydrophthalic | 7 | 10 | 10 | | 10 | 9 | |
| anhydride | | | | | | | |
| 2-ethyl-4- | 0.5 | 0.7 | 0.7 | 0.5 | 0.7 | 0.5 | / |
| methylimidazole | | | | | | | |
| Dimethylbenzylamine | / | 0.5 | / | / | 0.5 | / | 0.7 |
| Silica (the average | 70 | 80 | 100 | 70 | 80 | 75 | 90 |
| particle size is | | | | | | | |
| 10 μm, and the | | | | | | | |
| maximum particle | | | | | | | |
| size is 25 μm) | | | | | | | |
| Carbon black | 0.06 | 0.06 | 0.06 | 0.06 | 0.06 | 0.06 | 0.06 |
| 3-glycidyloxypropyltri- | 1 | 1 | 1 | 1 | 1 | 1 | 1 |
| methoxysilane | | | | | | | |
| Diluent | 0.7 | 0.7 | 0.7 | 0.7 | / | 0.7 | 0.7 |
| (ADEKA: ED-5095) | | | | | | | |
| Diluent | / | / | / | / | 0.7 | / | / |
| (ERISYS GE-5) | | | | | | | |
| Viscosity | 383 | 450 | 324 | 530 | 390 | 524 | 356 |
| (unit: Pa · s) | | | | | | | |
| Warpage | 0 | 0.3 | 0.2 | 0.4 | 0.5 | 1 | 0.7 |
| (unit: mm) | | | | | | | |
| Modulus | 8.2 | 7.3 | 7.4 | 7.1 | 6.4 | 5.3 | 5.8 |
| (unit: GPa) | | | | | | | |
| Silicon adhesion | 18 | 12 | 20 | 12 | 14 | 8 | 7 |
| (unit: MPa) | | | | | | | |

It can be known from the above-mentioned table that embodiments 1-5 have more excellent performances than comparative examples 1-2. Due to the adoption of the epoxy resin with the flexible chain segment in a certain content ratio in embodiments 1-5 and the combination of a curing system and a dilution system, more excellent modulus and warpage are achieved, and the silicon interface, adhesion is also obviously superior to that in the comparative examples. Moreover, it can be seen from embodiment I and embodiment 4 that the compounded curing agent can have a more stable curing effect and the elf bet of the die Sealant is better. In addition, it is also found by an inventor of the present application that the diluent with aryls shows more excellent effects in the die sealant system provided by the present application. The die sealant provided by the present application can achieve more stable protection for the chips by the good silicon interface adhesion and relieve bending cracks of the silicon wafer due to high modulus and low warpage. Moreover, the die sealant is a liquid at normal temperature, low in viscosity, good in flowability and suitable for die-pressing packaging.

The die sealant for chip packaging and the packaging structure provided in the embodiments of the present application have been introduced in detail as above. Specific individual examples are applied herein to describe the principle and implementations of the present application. The descriptions of the above-mentioned embodiments are only intended to help understand the method and core concept of the present application. At the same time, those skilled in the art may, based on the concept of the present application, make modifications with respect to the specific implementations and the application scope. In conclusion, the content of this specification shall not be understood as a limitation on the present application.

What is claimed is:

1. A die sealant for chip packaging, comprising the following components in parts by weight: 5-20 parts by weight of epoxy resin, 5-20 parts by weight of curing agent, 0.1-1.2 parts by weight of curing accelerator, 70-100 parts by weight of inorganic filler, 0.5-2.5 parts by weight of coupling agent and 0.1-15 parts by weight of diluent;
wherein the epoxy resin has a structure as shown in a formula (I): 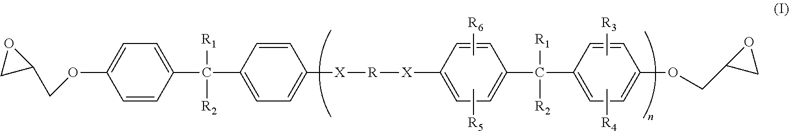
in the formula (I), each of R1 and R2 is independently selected from linear or branched alkyls of H or C1-C10, each of R3, R4, R5 and R6 is independently selected from a hydrogen atom, a methyl or a halogen, X is selected from —O—, —COO— or —OCH(CH3)O—, and R is —CH2CH2—(OCH2CH2)m- or —CH(CH3)CH2—(OCH(CH3)CH2)m—wherein in is an integer within a range of 0-5, and n is an integer within a range of 1-10;
wherein the diluent is a p-tert-butylphenol epoxy resin diluent; and
the curing agent comprises methyl nadic anhydride and methylhexahydrophthalic anhydride which are in a mass ratio of 1:1.

2. The die sealant for chip packaging of claim 1, wherein the epoxy resin has a structure as shown in a formula (II): 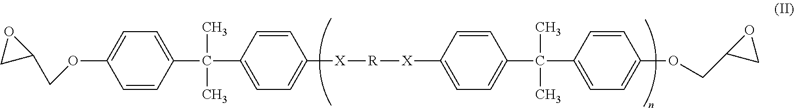
wherein X is —OCH(CH3)O—, and n is an integer within a range of 1-5.

3. The die sealant for chip packaging of claim 1, wherein the inorganic filler is silica, wherein a particle size of silica is within a range of 0.1-75 μm.

4. The die sealant for chip packaging of claim 1, wherein the diluent has the total chloride content of less than or equal to 200 ppm.

5. The die sealant for chip packaging of claim 1, wherein the die sealant for chip packaging further contains 0.02-0.1 part by weight of colorant.

6. The die sealant for chip packaging of claim 1, consisting of the following components in parts by weight: 5-20 parts by weight of the epoxy resin, 5-20 parts by weight of the curing agent, 0.1-1.2 parts by weight of the curing accelerator, 70-100 parts by weight of the inorganic filler, 0.1-15 parts by weight of the diluent and 0.02-0.1 part by weight of the colorant.

7. A chip packaging structure, wherein the chip packaging structure comprises chips etched on a silicon wafer and a packaging layer covering the silicon wafer, wherein the packaging layer is in contact with the silicon wafer and covers the chips, and the packaging layer comprises the die sealant of claim 1.
